(19) United States
(12) Patent Application Publication
(10) Pub. No.: US 2021/0349392 A1
(43) Pub. Date: Nov. 11, 2021

(54) METHOD FOR CREATION OF DIFFERENT DESIGNS BY COMBINING A SET OF PRE-DEFINED DISJOINT MASKS

(71) Applicant: North Sea Investment Company Ltd., Futian District, Shenzhen City (CN)

(72) Inventor: Soheil Gharahi, Santa Clara, CA (US)

(73) Assignee: North Sea Investment Company Ltd., Shenzhen City (CN)

(21) Appl. No.: 17/278,226

(22) PCT Filed: Dec. 11, 2019
(86) PCT No.: PCT/US19/65579

§ 371 Date: Mar. 19, 2021

Related U.S. Application Data
(60) Provisional application No. 62/780,140, filed on Dec. 14, 2018.

(51) Int. Cl. G03F 7/20; H01L 21/027

(52) U.S. Cl. CPC G03F 7/2022; G03F 7/039; H01L 21/0274

(57) ABSTRACT

Described are methods for enabling the creation of multiple similar designs by utilizing sets of multiple, disjoint fabrication masks. A first set of device features may be formed from a material layer in a first portion of a die area of a semiconductor substrate based on a first photolithographic exposure. A second set of device features may be formed from the material layer in a second portion of the die area of the semiconductor substrate based on a second photolithographic exposure after the first photolithographic exposure. The first portion of the die area and the second portion of the die area may be non-overlapping.

### CLAIM OF PRIORITY

This application claims priority to U.S. Provisional Patent Application Ser. No. 62/780,140, filed on Dec. 14, 2018, titled “METHOD FOR CREATION OF DIFFERENT DESIGNS BY COMBINING A SET OF PRE-DEFINED DISJOINT MASKS,” and which is incorporated by reference in entirety.

### BACKGROUND

Integrated Circuit (IC) design and fabrication processes can be very long and arduous. Contemporary IC design and fabrication processes may be highly customized, and the time taken to move from a design concept to a working chip may be many months or even many years. Many techniques may be used in order to reduce the time to produce a working chip, some of which may incorporate design re-use.

Some techniques may involve the use of pre-silicon methods to reduce the design time. These methods may be deployed at the architectural level and the circuit design level, which may ultimately result in the creation of a custom set of masks for any single chip, even if they may merely be derivatives of a previous design.

### BRIEF DESCRIPTION OF THE DRAWINGS

The embodiments of the disclosure will be understood more fully from the detailed description given below and from the accompanying drawings of various embodiments of the disclosure. However, while the drawings are to aid in explanation and understanding, they are only an aid, and should not be taken to limit the disclosure to the specific embodiments depicted therein.

FIG. 1 illustrates a first photolithographic mask, a second photolithographic mask, and an Integrated Circuit (IC) die manufactured using the first photolithographic mask and the second photolithographic mask, in accordance with some embodiments of the disclosure.

FIGS. 2A-2F illustrate a manufacturing process involving a semiconductor substrate, a first photolithographic mask, and a second photolithographic mask, in accordance with some embodiments of the disclosure.

FIGS. 3A-3E illustrate another manufacturing process involving a semiconductor substrate, a first photolithographic mask, and a second photolithographic mask, in accordance with some embodiments of the disclosure.

FIG. 4 illustrates a first photolithographic mask, a second photolithographic mask, and an IC die manufactured using the first photolithographic mask and the second photolithographic mask, in accordance with some embodiments of the disclosure.

FIG. 5 illustrates an IC die having multiple die area portions, in accordance with some embodiments of the disclosure.

FIG. 6 illustrates a method for enabling the creation of multiple similar designs by utilizing multiple, disjoint fabrication masks, in accordance with some embodiments of the disclosure.

FIG. 7 illustrates a method for enabling the creation of multiple similar designs by utilizing multiple, disjoint fabrication masks, in accordance with some embodiments of the disclosure.

FIG. 8 illustrates a method for enabling the creation of multiple similar designs by utilizing multiple, disjoint fabrication masks, in accordance with some embodiments of the disclosure.

### DETAILED DESCRIPTION

In the following description, numerous details are discussed to provide a more thorough explanation of embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct electrical, mechanical, or magnetic connection between the things that are connected, without any intermediary devices. The term “coupled” means either a direct electrical, mechanical, or magnetic connection between the things that are connected or an indirect connection through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking, or in any other manner.

It is to be understood that the terms so used are interchangeable under appropriate circumstances such that the embodiments of the invention described herein are, for example, capable of operation in other orientations than those illustrated or otherwise described herein.

The terms “left,” “right,” “front,” “back,” “top,” “bottom,” “over,” “under,” and the like in the description and in the claims, if any, are used for descriptive purposes and not necessarily for describing permanent relative positions.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Disclosed herein are methods for enabling the creation of multiple similar designs by utilizing sets of multiple, disjoint fabrication masks, which may advantageously reduce design time and cost significantly. In various embodiments, an Integrated Circuit (IC) die may have a modular design, in which multiple Intellectual Property cores (IP) may serve as modules. The methods discussed herein may include re-using and/or combining already-created disjoint masks from previous designs in order to support new designs. In some embodiments, various modules of the modular design may be associated with system capacities or capabilities (such as processors, memory, radio circuitry, and so forth).

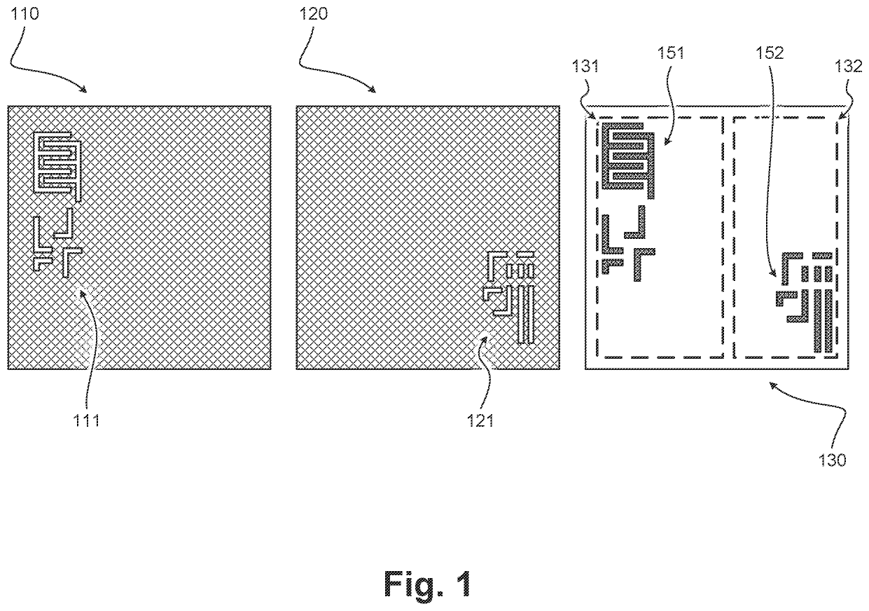

FIG. 1 illustrates a first photolithographic mask, a second photolithographic mask, and an IC die, in accordance with some embodiments of the disclosure. A first mask 110 may comprise a set of first mask features 111, while a second mask 120 may comprise a set of second mask features 121.

As discussed in further detail below, IC die 130 may be manufactured using first mask 110 and second mask 120. A first portion 131 of IC die 130 may comprise a set of first device features 151 formed using first mask 110 and its first mask features 111. Similarly, a second portion 132 of IC die 130 may comprise a set of second device features 152 formed using second mask 120 and its second mask features 121. In various embodiments, first portion 131 may be disjoint from second portion 132, and first device features 151 may be disjoint from second device features 152.

Device features 151 may correspond with a first module and/or a first IP of an overall design for IC die 130, and device features 152 may correspond with a second module and/or a second IP of the overall design. If one or more dedicated masks are created for first portion 131, and if one or more dedicated masks are created for second portion 132, the overall design or final design of IC die 130 may be created by using both the dedicated masks for first portion 131 and dedicated masks for second portion 132. As a result, in some embodiments, a final design of IC die 130 may include first device features 151 and second device features 152.

However, in other embodiments, the final design may instead include first device features 151 with another disjoint set of device features corresponding with another module and/or IP. Similarly, in other embodiments, the final design may include second design features 152 with yet another disjoint set of device features corresponding with yet another module and/or IP. Accordingly, the methods discussed herein may advantageously support the use of first mask 110 and second mask 120 for various different IC die designs.

For example, first mask 110 and/or second mask 120—along with one or more other masks, in some embodiments—may be used to form device features in one or more upper layers of an IC die design, where global routing may take place. In some embodiments, the one or more upper layers may comprise a metal layer, or a layer primarily comprising metal. In some embodiments, the one or more upper layers may comprise a redistribution layer. In some embodiments, features in a redistribution layer (such as interconnect or other wiring) may have one or more cross-sectional dimensions that are, on average, greater than the cross-sectional dimensions of other layers (e.g., other metal layers for redistribution layers primarily comprised of metal). Accordingly, features of a redistribution layer may have a greater cross-sectional height or cross-sectional width than features (e.g., interconnect) of another layer.

Following various design rules during the design process for global routing may accommodate decisions about which set of masks (e.g., which set of masks for global-routing device features) may be used to meet given design needs or design criteria. For example, the various design rules may support decisions to use masks corresponding to a variety of design features that may support different capacities or capabilities (as discussed further herein). Accordingly, the methods discussed herein may advantageously facilitate and/or enable rapid prototyping of IC dies with modular designs by accommodating distinct masking corresponding with different IPs.

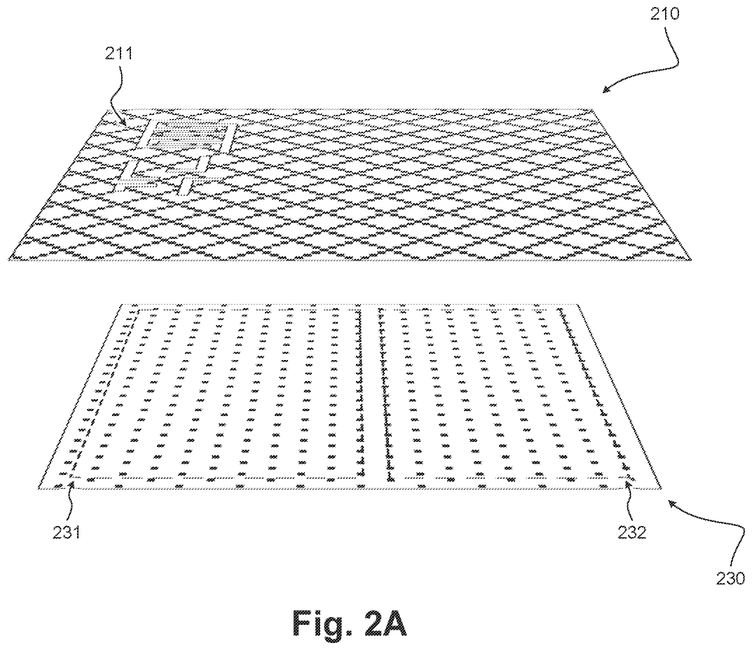

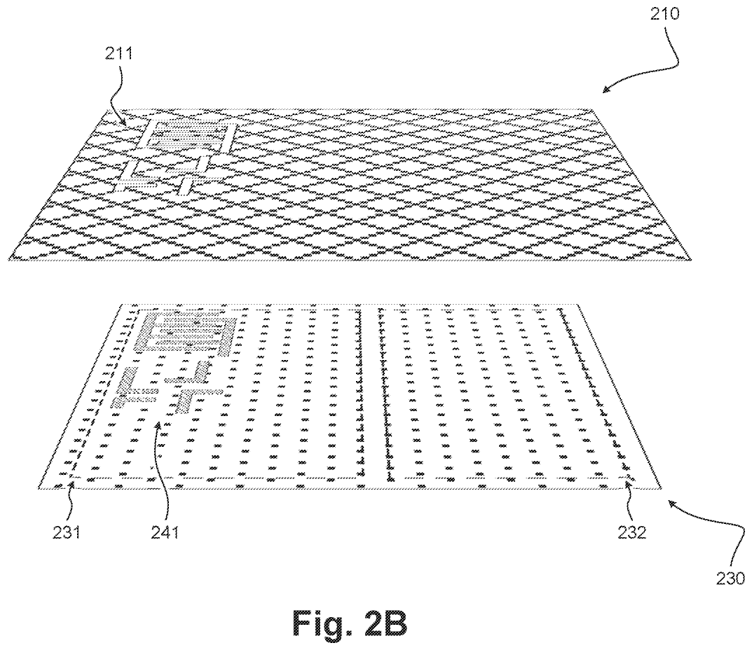

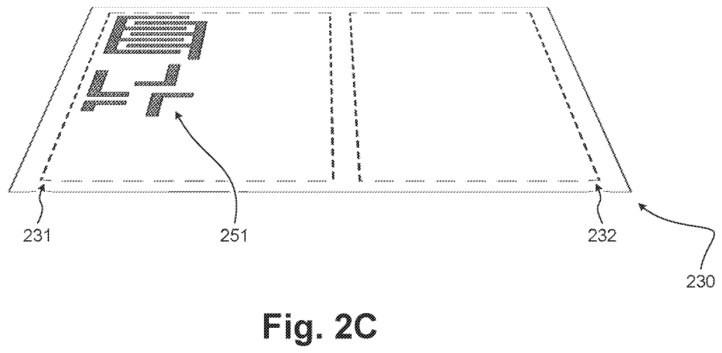

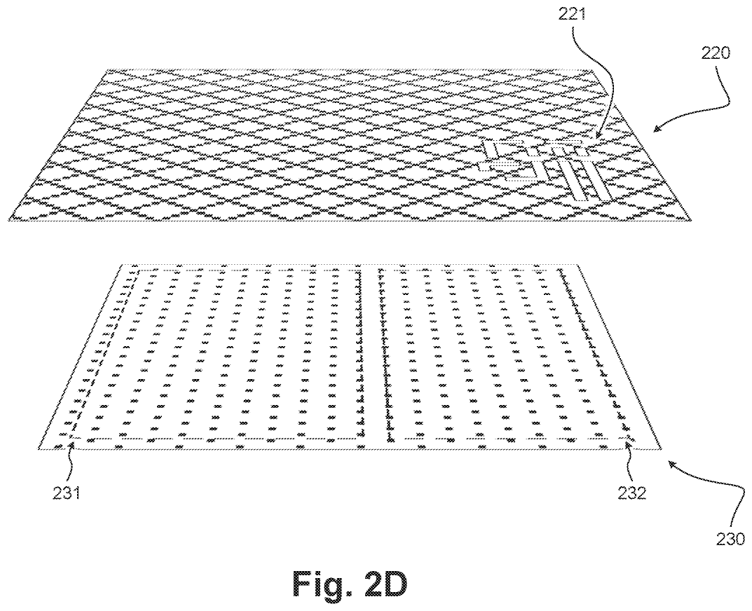

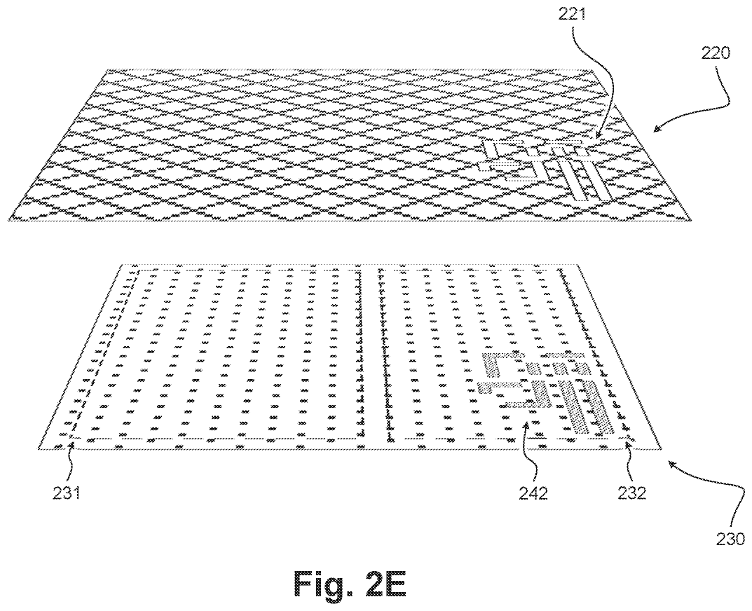

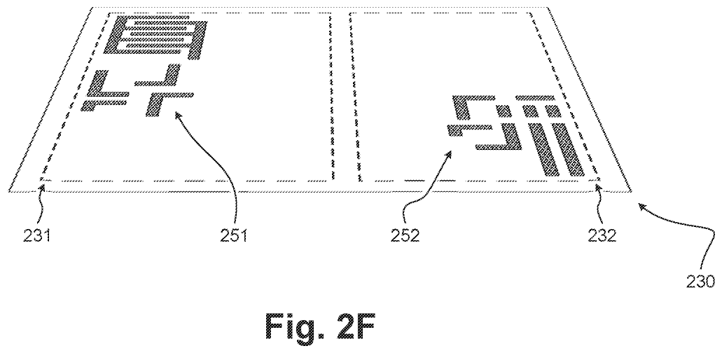

FIGS. 2A-2F illustrate a manufacturing process involving a semiconductor substrate, a first photolithographic mask, and a second photolithographic mask, in accordance with some embodiments of the disclosure. The semiconductor substrate may comprise a silicon wafer, such as a silicon wafer in the midst of a photolithographic IC fabrication process. In various embodiments, the semiconductor substrate may be covered or coated with a photoresist layer.

As depicted in FIG. 2A, a die area 230 of the semiconductor substrate may have a first portion 231 and a second portion 232. First portion 231 and second portion 232 may be disjoint and/or spaced from each other across the semiconductor substrate. A first mask 210 may be placed into a first alignment with at least first portion 231 of die area 230. First mask 210 may include a set of first mask features 211. The first alignment may place first mask features 211 in a position corresponding with first portion 231 of die area 230.

In FIG. 2B, a first photolithographic exposure may be performed on die area 230 through first mask 210. A light of the exposure may pass through first mask features 211 and may interact with first photoresist areas 241 of first portion 231 (and may not interact with photoresist of second portion 232).

Following the first photolithographic exposure, first photoresist areas 241 may be weakened. First photoresist areas 241 may then be dissolved and removed by subsequent processing, leaving channels exposing the remaining portions of the semiconductor substrate under the photoresist. A material (e.g., a metal material, or a material comprising metal) may then be deposited over die area 230, and may fill the channels exposed by the removal of first photoresist areas 241.

In FIG. 2C, the remainder of the photoresist outside of first photoresist areas 241 may be removed, thereby forming first device features 251 in first portion 231. First device features 251 of die area 230 may thus be formed from the material (e.g., metal material) that had filled the channels exposed by the removal of first photoresist areas 241, which were in turn based on the first photolithographic exposure. Various embodiments may use a positive tone photoresist, and/or a lift-off process.

The processing of FIGS. 2D-2F may be substantially similar to the processing of FIGS. 2A-2C, but with respect to second portion 232 instead of first portion 231. In various embodiments, the semiconductor substrate may be covered or coated with another photoresist layer (which may be substantially similar to the sorts of photoresist layers available for the setup of FIG. 2A).

In FIG. 2D, a second mask 220 may be placed into a second alignment with at least second portion 232 of die area 230. Second mask 220 may include a set of second mask features 221. The second alignment may place second mask features 221 in a position corresponding with second portion 232 of die area 230.

In FIG. 2E, a second photolithographic exposure may be performed on die area 230 through second mask 220. A light of the exposure may pass through second mask features 221 and may interact with second photoresist areas 242 of second portion 232 (and may not interact with photoresist of first portion 231).

Following the second photolithographic exposure, second photoresist areas 242 may be weakened. Second photoresist areas 242 may then be dissolved and removed by subsequent processing, leaving channels exposing the remaining portions of the semiconductor substrate under the photoresist. A material (e.g., a metal material, or a material comprising metal) may then be deposited over die area 230, and may fill the channels exposed by the removal of second photoresist areas 242.

In FIG. 2F, the remainder of the photoresist outside of second photoresist areas 242 may be removed, thereby forming second device features 252 in second portion 232. Second device features 252 of die area 230 may thus be formed from the material (e.g., metal material) that had filled the channels exposed by the removal of second photoresist areas 242, which were in turn based on the second photolithographic exposure.

Following these processing steps, die area 230 may comprise first device features 251 in first portion 231 and second device features 252 in second portion 232. In various embodiments, first portion 231 may be spaced from second portion 232, and/or first portion 231 may be disjoint from second portion 232, and/or first portion 231 may be non-overlapping with second portion 232. For various embodiments, the metal material of first device features 251 and/or second device features 252 may comprise portions of a metal layer of the semiconductor substrate.

For some embodiments, portions of the semiconductor substrate under first device features 251 and/or portions of the semiconductor substrate under second device features 252 may comprise analog signaling regions, and/or routing operable to route analog signals. Some portions of die area 230 may accordingly have routing for digital signals, while other portions of die area 230—including portions of die area 230 formed by first mask 210 and/or second mask 220—may have routing more suitable for analog signals.

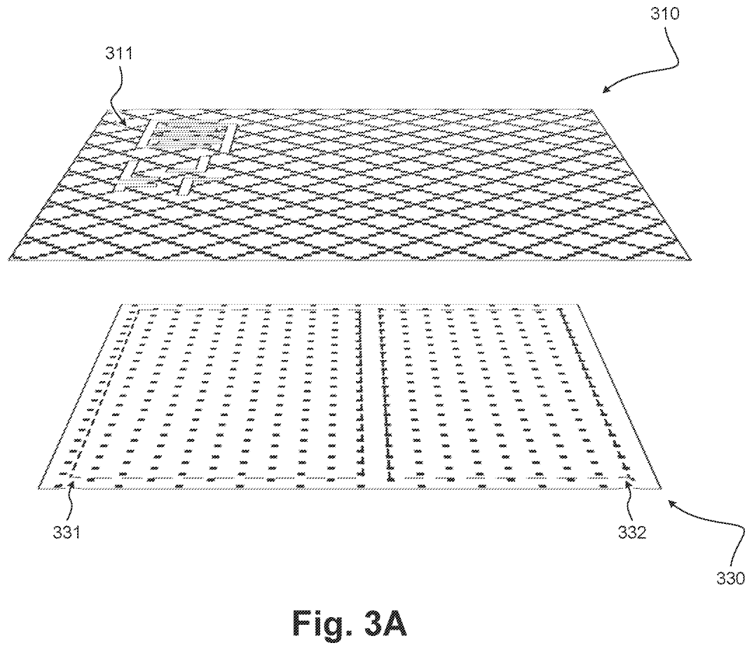

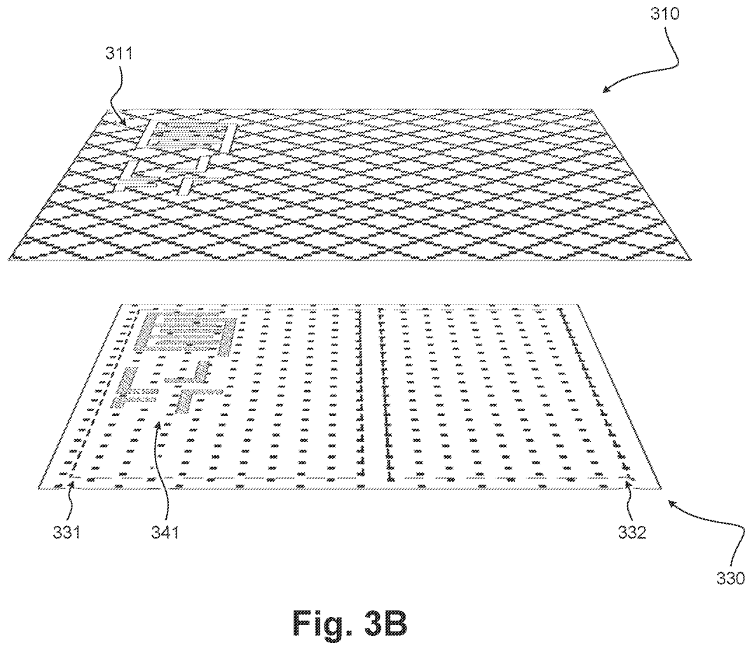

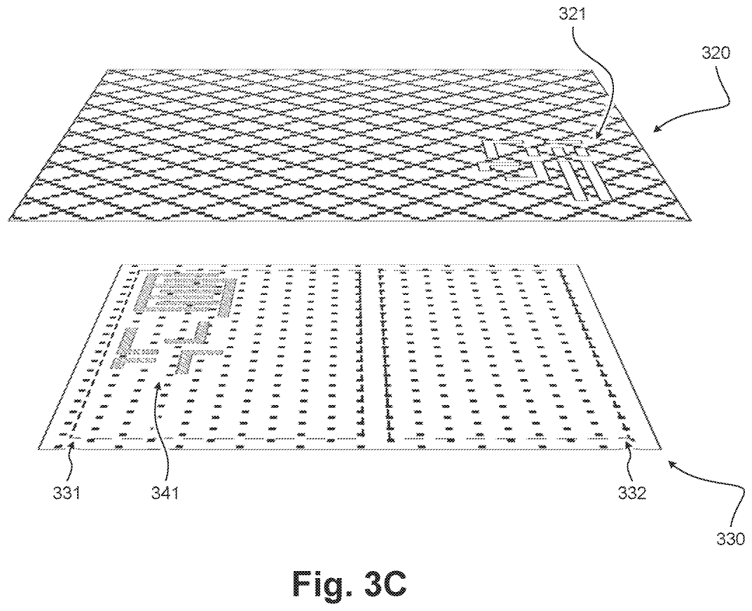

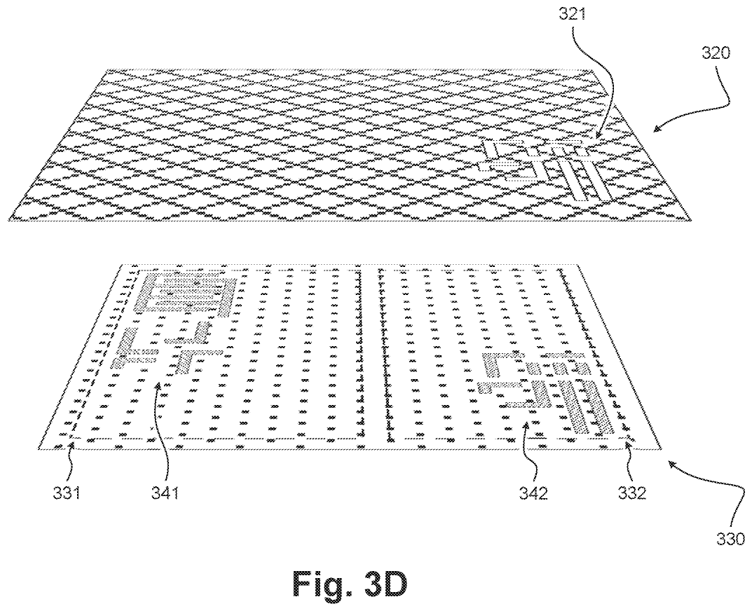

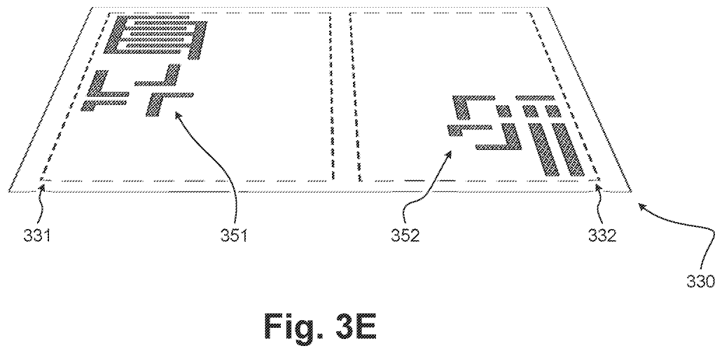

FIGS. 3A-3E illustrate another manufacturing process involving a semiconductor substrate, a first photolithographic mask, and a second photolithographic mask, in accordance with some embodiments of the disclosure. FIGS. 3A and 3B may pertain to a die area 330 having a first portion 331 and a second portion 332, and a first mask 310 having a set of first mask features 311.

The process of FIGS. 3A and 3B may be substantially similar to the process of FIGS. 2A and 2B. Following a first photolithographic exposure through first mask features 311, first photoresist areas 341 may be weakened. However, instead of dissolving and removing a photoresist in first photoresist areas 341, depositing a material to fill the channels exposed by first photoresist areas 341, removing the remainder of the photoresist, and covering or coating the semiconductor substrate with another photoresist layer, a second photolithographic exposure may be performed on the same layer of photoresist.

So, in FIG. 3C, a second mask 320 may be placed into a second alignment with at least second portion 332 of die area 330. Second mask 320 may include a set of second mask features 321. The second alignment may place second mask features 321 in a position corresponding with 332 of die area 330.

In FIG. 3D, a second lithographic exposure may be performed on die area 330 through second mask 310. A light of the exposure may pass through second mask features 321 and may interact with second photoresist areas 342 of second portion 332 (and may not interact with areas of first portion 331).

So, following the second photolithographic exposure, both first photoresist areas 341 and second photoresist areas 342 may be weakened. Both first photoresist areas 341 and second photoresist areas 341 may then be dissolved and removed by subsequent processing, leaving channels exposing the remaining portions of the semiconductor substrate under the photoresist. A material (e.g., a metal material, or a material comprising metal) may then be deposited over die area 330, and may fill the channels exposed by the removal of first photoresist areas 341 and second photoresist areas 342.

As a result, in some embodiments, after one photolithographic exposure, the dissolving and removal of various photoresist areas may be deferred until another photolithographic exposure has been performed.

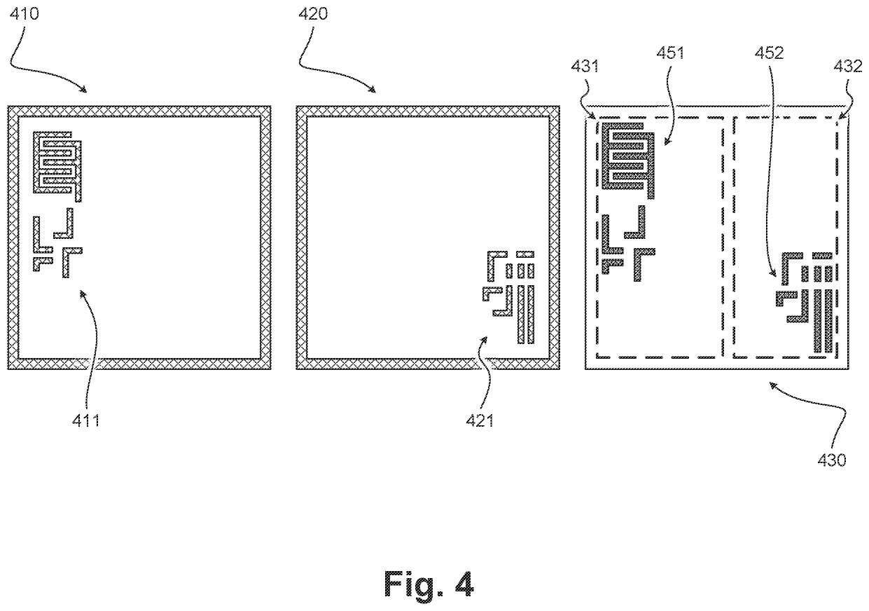

The photoresist layers discussed above are depicted as being positive photoresist layers (i.e., a photoresist material whose structural integrity is degraded by exposure to light). However, some embodiments may make use of negative photoresist layers (i.e., a photoresist material whose structural integrity is strengthened by exposure to light). FIG. 4 illustrates a first photolithographic mask, a second photolithographic mask, and an IC die manufactured using the first photolithographic mask and the second photolithographic mask, in accordance with some embodiments of the disclosure. A first mask 410 may comprise a set of first mask features 411, while a second mask 420 may comprise a set of second mask features 421.

In comparison with first mask 110, first mask 410 may be designed such that areas of a photoresist layer exposed to light outside of first mask features 411 may become strengthened. The remaining photoresist areas (i.e., photoresist areas corresponding with first mask features 411) may then be dissolved and removed by subsequent processing, leaving channels exposing the areas of the photoresist layer exposed to light outside of first mask features 411. A material (e.g., a metal material, or a material comprising metal) may then be deposited over die area 430, and may fill the channels exposed by the removal of the non-exposed photoresist. Various embodiments may use a negative tone photoresist and/or an etch process (e.g., for depositing a layer of material, such as a metal material, then depositing a layer of photoresist, then etching away metal not covered by patterned photoresist).

IC dies created in accordance with the methods discussed herein may advantageously be designed to implement programmable semiconductor interposers to which chiplets may be mounted. A programmable semiconductor interposer may be, or may include, an IC. Such an interposer may provide a substrate to make electrical connection to and/or between one or more chiplets. In turn, chiplets may be, or may include, semiconductor dies, ICs, and/or semiconductor chips. The chiplets may have smaller footprints (e.g., smaller x-dimensions and y-dimensions) than the interposer, and in various embodiments, multiple chiplets may fit within the footprint of the interposer.

The incorporation of components having different capacities and capabilities into an IC die via chiplets mounted on an interconnect substrate may advantageously support rapid prototyping. Meanwhile, some chiplets providing capacities and capabilities such as radio circuitry or other wireless communication circuitry may benefit from the inclusion of routing for analog signaling on the interposer. Accordingly, the methods discussed herein may advantageously support the use of a programmable semiconductor interconnect and one or more chiplets by allowing a user to defer some fabrication and/or manufacturing process steps, thereby providing flexibility as to the modules or IPs to be incorporated into an IC's design.

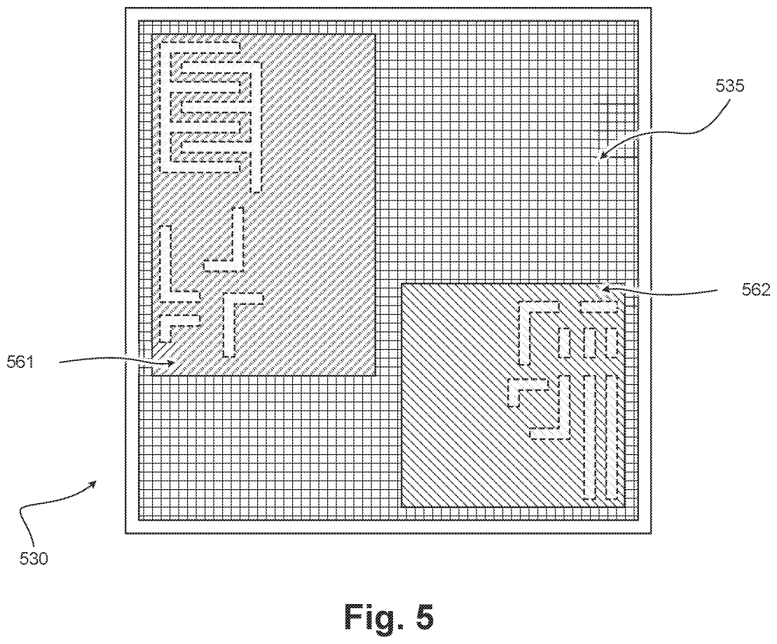

For example, FIG. 5 illustrates an IC die having multiple die area portions, in accordance with some embodiments of the disclosure. An IC die 530 may comprise a programmable semiconductor interposer portion 535. A first chiplet 561 may be mounted to IC die 530 in a region including a set of first device features, and a second chiplet 562 may be mounted to IC die 530 in a region including a set of second device features.

The methods discussed herein may advantageously accommodate the placement of chiplets having associated global routing onto programmable semiconductor interposers. Such mounted chiplets may advantageously tolerate the type of relatively slight imperfections in alignments between device features created by a first mask and device features created by a second mask, since the mounting or placement of chiplets onto a programmable semiconductor interposer may be tolerant to alignment imperfections. In contrast, previous design approaches have not been tolerant of alignment imperfections, and a multiple-masking method of the sort disclosed herein would accordingly be undesirable for such designs.

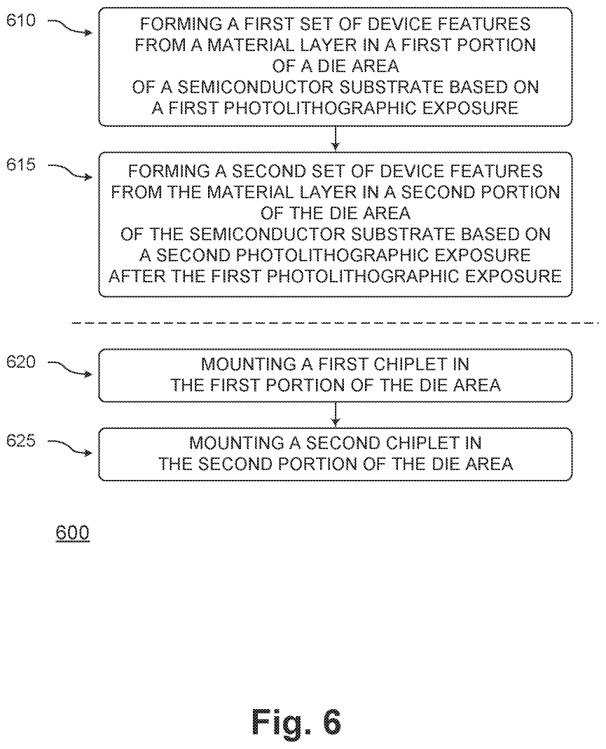

FIG. 6 illustrates a method for enabling the creation of multiple similar designs by utilizing multiple, disjoint fabrication masks, in accordance with some embodiments of the disclosure. A method 600 may comprise a forming 610 and a forming 615. In some embodiments, method 600 may also comprise a mounting 620 and/or a mounting 625.

In forming 610, a first set of device features (e.g., first device features 251) may be formed from a material layer in a first portion of a die area of a semiconductor substrate (e.g., first portion 231 of die area 230) based on a first photolithographic exposure. In forming 615, a second set of device features (e.g. second device features 252) may be formed from the material layer in a second portion of the die area of the semiconductor substrate (e.g., second portion 232 of die area 230) based on a second photolithographic exposure after the first photolithographic exposure. The first portion of the die area and the second portion of the die area may be non-overlapping.

In some embodiments, the first set of device features may be formed using a first photolithographic mask, and/or the second set of device features is formed using a second photolithographic mask. For some embodiments, at least one of the first set of device features and the second set of device features is formed using a positive photoresist.

In some embodiments, the material layer may comprise a metal layer. For some embodiments, the material layer may comprise a redistribution layer.

In some embodiments, a portion of the semiconductor substrate under at least one of the first set of device features and the second set of device features comprises an analog signaling region (e.g., a region having design features to support global routing for analog signaling). For various embodiments, the semiconductor substrate may comprise a silicon wafer. In some embodiments, the die area may comprise features for a programmable semiconductor interposer (e.g., programmable semiconductor interposer portion 535).

For some embodiments, in mounting 620, a first chiplet (e.g., first chiplet 561) may be mounted in the first portion of the die area. For some embodiments, in mounting 625, a second chiplet (e.g., second chiplet 562) may be mounted in the second portion of the die area.

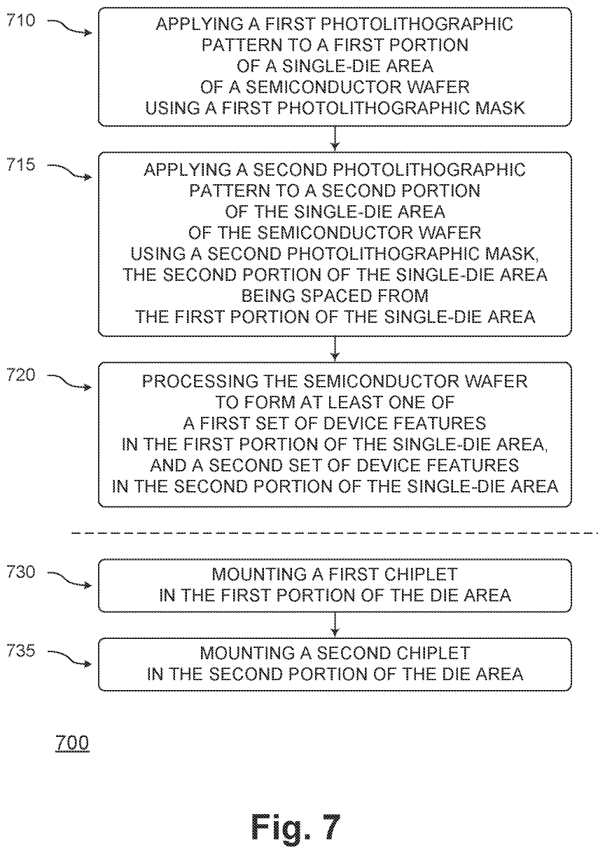

FIG. 7 illustrates a method for enabling the creation of multiple similar designs by utilizing multiple, disjoint fabrication masks, in accordance with some embodiments of the disclosure. A method 700 may comprise an applying 710, an applying 715, and a processing 720. In some embodiments, method 700 may comprise a mounting 730 and/or a mounting 735.

In applying 710, a first photolithographic pattern (e.g., a pattern of first mask features 211) may be applied to a first portion of a single-die area (e.g., first portion 231 of die area 230) of a semiconductor wafer using a first photolithographic mask (e.g., first mask 210). In applying 715, a second photolithographic pattern (e.g., a pattern of second mask features 221) may be applied to a second portion of the single-die area (e.g., second portion 232 of die area 230) of the semiconductor wafer using a second photolithographic mask (e.g., second mask 220). The second portion of the single-die area may be spaced from the first portion of the single-die area. In processing 720, the semiconductor wafer may be processed to form at least one of a first set of device features (e.g., first device features 251) in the first portion of the single-die area, and a second set of device features (e.g., second device features 252) in the second portion of the single-die area.

In some embodiments, at least a portion of the first set of device features and at least a portion of the second set of device features may be formed in a metal layer and/or a redistribution layer. For some embodiments, at least one of the first photolithographic pattern and the second photolithographic pattern may be applied to a positive photoresist. In some embodiments, a portion of the semiconductor wafer under the first set of device features and/or the second set of device features may comprise an analog signaling region.

In some embodiments, the single-die area may comprise features for a programmable semiconductor interposer (e.g., programmable semiconductor interposer portion 535). For some embodiments, in mounting 730, a first chiplet may be mounted in the first portion of the die area. For some embodiments, in mounting 735, a second chiplet may be mounted in the second portion of the die area.

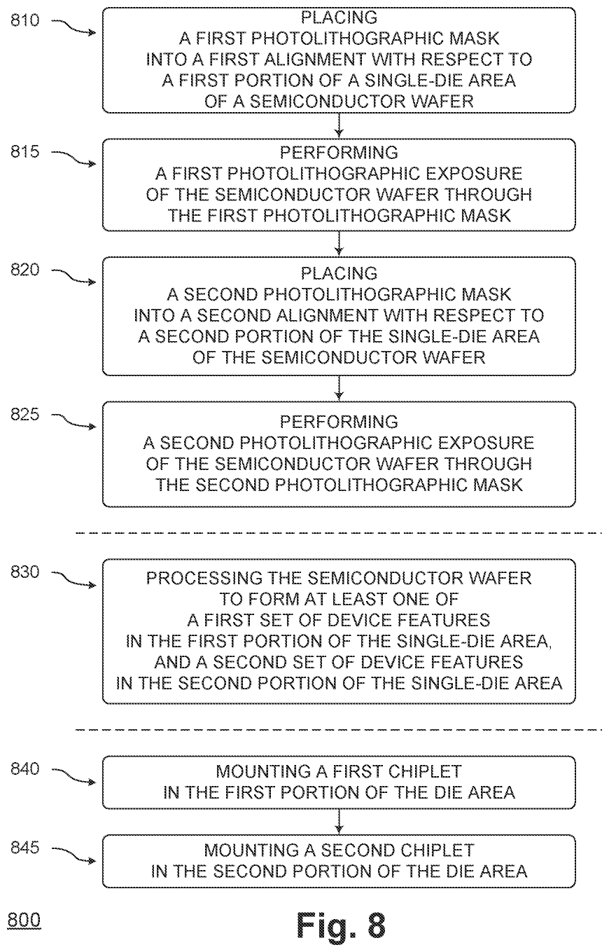

FIG. 8 illustrates a method for enabling the creation of multiple similar designs by utilizing multiple, disjoint fabrication masks, in accordance with some embodiments of the disclosure. A method 800 may comprise a placing 810, a performing 815, a placing 820, and a performing 825. Method 800 may also comprise a processing 830, a mounting 840, and/or a mounting 845.

In placing 810, a first photolithographic mask (e.g., first mask 210 may be placed into a first alignment with respect to a first portion of a single-die area (e.g., first portion 231 of die area 230) of a semiconductor wafer. In performing 815, a first photolithographic exposure of the semiconductor wafer through the first photolithographic mask may be performed. In placing 820, a second photolithographic mask (e.g., second mask 220) may be placed into a second alignment with respect to a second portion of the single-die area (e.g., second portion 232 of die area 230) of the semiconductor wafer. In performing 825, a second photolithographic exposure of the semiconductor wafer through the second photolithographic mask may be performed. The first portion of the single-die area and the second portion of the single-die area may be disjoint.

In some embodiments, in processing 830, the semiconductor wafer may be processed to form at least one of a first set of device features (e.g., first device features 251) in the first portion of the single-die area, and a second set of device features (e.g., second device features 252) in the second portion of the single-die area.

For some embodiments, a portion of the semiconductor wafer under at least one of the first set of device features and the second set of device features may comprise an analog signaling region. In some embodiments, the single-die area may comprise features for a programmable semiconductor interposer (e.g., programmable semiconductor interposer portion 535). For some embodiments, in mounting 240, a first chiplet (e.g., first chiplet 561) may be mounted in the first portion of the die area. For some embodiments, in mounting 245, a second chiplet (e.g., second chiplet 562) may be mounted in the second portion of the die area.

Although the actions in the flowcharts with reference to FIGS. 6-8 are shown in a particular order, the order of the actions can be modified. Thus, the illustrated embodiments can be performed in a different order, and some actions may be performed in parallel. Some of the actions and/or operations listed in FIGS. 6-8 are optional in accordance with certain embodiments. The numbering of the actions presented is for the sake of clarity and is not intended to prescribe an order of operations in which the various actions must occur. Additionally, operations from the various flows may be utilized in a variety of combinations.

In some embodiments, an apparatus may comprise means for performing various actions and/or operations of the methods of FIGS. 6-8.

Moreover, in some embodiments, machine readable storage media may have executable instructions that, when executed, cause one or more processors to perform an operation comprising method 600, method 700, or method 800. Such machine readable storage media may include any of a variety of storage media, like magnetic storage media (e.g., magnetic tapes or magnetic disks), optical storage media (e.g., optical discs), electronic storage media (e.g., conventional hard disk drives, solid-state disk drives, or flash-memory-based storage media), or any other tangible storage media or non-transitory storage media.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to IC chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-20. (canceled)

21. A method comprising:
forming a first set of device features from a material layer in a first portion of a die area of a semiconductor substrate based on a first photolithographic exposure; and
forming a second set of device features from the material layer in a second portion of the die area of the semiconductor substrate based on a second photolithographic exposure after the first photolithographic exposure;
wherein the first portion of the die area and the second portion of the die area are non-overlapping.

22. The method of claim 20,
wherein forming the first set of device features comprises applying a first photolithographic mask, and
wherein forming the second set of device features comprises applying a second photolithographic mask.

23. The method of claim 20,
wherein forming at least one of the first set of device features and the second set of device features comprises applying a positive photoresist.

24. The method of claim 20,
wherein the material layer comprises a metal layer.

25. The method of claim 20,
wherein the material layer comprises a redistribution layer.

26. The method of claim 20,
wherein a portion of the semiconductor substrate under at least one of the first set of device features and the second set of device features comprises an analog signaling region.

27. The method of claim 20, wherein the semiconductor substrate comprises a silicon wafer.

28. The method of claim 20, wherein the die area comprises features for a programmable semiconductor interposer.

29. The method of claim 20, comprising:
mounting a first chiplet in the first portion of the die area; and
mounting a second chiplet in the second portion of the die area.

30. A method comprising:
applying a first photolithographic pattern to a first portion of a single-die area of a semiconductor wafer using a first photolithographic mask;
applying a second photolithographic pattern to a second portion of the single-die area of the semiconductor wafer using a second photolithographic mask, the second portion of the single-die area being spaced from the first portion of the single-die area; and
processing the semiconductor wafer to form at least one of a first set of device features in the first portion of the single-die area, and a second set of device features in the second portion of the single-die area.

31. The method of claim 30,
wherein at least a portion of the first set of device features and at least a portion of the second set of device features are formed in at least one of: a metal layer, and a redistribution layer.

32. The method of claim 0,
wherein at least one of the first photolithographic pattern and the second photolithographic pattern is applied to a positive photoresist.

33. The method of claim 0,
wherein a portion of the semiconductor wafer under at least one of the first set of device features and the second set of device features comprises an analog signaling region.

34. The method of claim 0,
wherein the single-die area comprises features for a programmable semiconductor interposer.

35. The method of claim 0, comprising:
mounting a first chiplet in the first portion of the die area; and
mounting a second chiplet in the second portion of the die area.

36. A method comprising:
placing a first photolithographic mask into a first alignment with respect to a first portion of a single-die area of a semiconductor wafer;
performing a first photolithographic exposure of the semiconductor wafer through the first photolithographic mask;
placing a second photolithographic mask into a second alignment with respect to a second portion of the single-die area of the semiconductor wafer; and
performing a second photolithographic exposure of the semiconductor wafer through the second photolithographic mask,
wherein the first portion of the single-die area and the second portion of the single-die area are disjoint.

37. The method of claim 0, comprising:
processing the semiconductor wafer to form at least one of a first set of device features in the first portion of the single-die area, and a second set of device features in the second portion of the single-die area.

38. The method of claim 0,
wherein a portion of the semiconductor wafer under at least one of the first set of device features and the second set of device features comprises an analog signaling region.

39. The method of claim 0,
wherein the single-die area comprises features for a programmable semiconductor interposer.

40. The method of claim 0, comprising:
mounting a first chiplet in the first portion of the die area; and
mounting a second chiplet in the second portion of the die area.
